(19) United States
(12) Patent Application Publication
(10) Pub. No.: US 2002/0172765 A1
(43) Pub. Date: Nov. 21, 2002

(54) Mouth ring for forming a honeycomb-shaped green product, method for fabricating a mouth ring to form a honeycomb-shaped green product and apparatus for fabricating a mouth ring to form a honeycomb-shaped green product

(75) Inventors: Yukinori Nakamura, Nagoya-city (JP); Yoshimasa Kondo, Nagoya City (JP)

Correspondence Address: BURR & BROWN, PO BOX 7068, SYRACUSE, NY, 13261-7068, US

(73) Assignee: NGK Insulators, Ltd., Nagoya-City (JP)

(21) Appl. No.: 10/144,551

(22) Filed: May 13, 2002

Related U.S. Application Data
(60) Provisional application No. 60/300,970, filed on Jun. 26, 2001.

(30) Foreign Application Priority Data
May 17, 2001 (JP) 2001-147,750

(51) Int. Cl. C23C 16/00; C23C 16/26

(52) U.S. Cl. 427/249.7; 427/255.28; 427/249.8; 427/569; 428/116

(57) ABSTRACT

The back side space of a mouth ring for forming a honeycomb-shaped green product is evacuated by means of a pressure difference-creating means constructed of a pressure regulating chamber and a pump, and then, the pressure in the back side space of the mouth ring is set to be tenth or below of the pressure in the front space of the mouth ring. Then, a raw material gas is introduced and excited to generate a plasma raw material gas, which is introduced into the mouth ring efficiently commensurate with the pressure difference created by means of the pressure difference-creating means. As a result, a thin film made of diamond or diamond-like carbon is made in the mouth ring in good quality.

### BACKGROUND OF THE INVENTION

1. Field of the Invention

This invention relates to a mouth ring for forming a honeycomb-shaped green product, a method for fabricating a mouth ring to form a honeycomb-shaped green product and an apparatus for fabricating a mouth ring to form a honeycomb-shaped green product.

2. Description of the Prior Art

With the miniaturization and the advancement of a product fabricated in a given shape, a mouth ring to form the green product becomes complicated and be miniaturized. Particularly, since a honeycomb-shaped green product for an automobile has an extremely complicated structure, an extremely high precision is required for a mouth ring for forming the honeycomb-shaped green product.

FIG. 1 is a perspective view showing a portion of a mouth ring for forming a honeycomb-shaped green product, and FIG. 2 is a back side view of the portion of the mouth ring shown in FIG. 1.

As is shown in FIGS. 1 and 2, a mouth ring 1 for forming a honeycomb-shaped green product includes a circular introducing portion 2 in the back side, a rectangular injecting portion 4 and a wringing portion 3 between the circular introducing portion 2 and the rectangular injecting portion 4. A green product material is introduced into the mouth ring 1 from the circular introducing portion 2, wrung at the wringing portion 3 and injected from the rectangular injecting portion 4, to form a given honeycomb-shaped green product.

As mentioned above, the green product material is introduced from the circular introducing portion 2, and then, passed through and injected from the wringing portion 3 and the rectangular injecting portion 4 under a given pressure. Therefore, at the time when the green product material is passed through, a large frictional force is created between the green product material and the circular introducing portion 2, the wringing portion 3 and the rectangular injecting portion 4. As a result, there may be some problems in wear for the circular introducing portion 2, the wringing portion 3 and the rectangular injecting portion 4.

Particularly, since the green product material is wrung at the wringing portion 3 when it is injected from the circular introducing portion 2 to the rectangular injecting portion 4, a large fictional force is created at the wringing portion 3. Conventionally, therefore, a hard film which is made of iron boride, chromium carbide, aluminum oxide, titanium carbide, titanium nitride or titanium carbon nitride is made in the mouth ring 1 by means of a CVD method or the like, so as to enhance the wear-resistance.

Although such an iron boride film has a larger hardness, however, it can not have a hardness enough to withstand the long time use under the large wear condition. Therefore, the use of such a hard film can not impart a sufficient wear-resistance for the mouth ring 1.

### SUMMERY OF THE INVENTION

It is an object of the present invention to provide mouth ring for forming a honeycomb-shaped green product which has a wear resistance enough to withstand the long time use under a large wear condition, a method for fabricating the same mouth ring and an apparatus for fabricating the same mouth ring.

For achieving the above object, this invention relates to a mouth ring for forming a honeycomb-shaped green product, comprising:

a circular introducing portion to introduce a given green product material,

a rectangular injecting portion to inject the green product material,

a wringing portion to wring out the green product material of the circular introducing portion to the rectangular injecting portion, the wringing portion being located between the circular introducing portion and the rectangular injecting portion, and

a thin film made of diamond or diamond-like carbon which is made at portions of the circular introducing portion, the rectangular injecting portion and the wringing portion to which the green product material is contacted.

Also, this invention relates to a method for fabricating a mouth ring to form a honeycomb-shaped green product which includes a circular introducing portion to introduce a green product material, a rectangular injecting portion to inject the green product material, and a wringing portion, which is located between the circular introducing portion and the rectangular injecting portion, to wring out the green product material of the circular introducing portion to the rectangular injecting portion, comprising the steps of:

preparing a plasma CVD apparatus,

setting the mouth ring in the plasma CVD apparatus,

creating a pressure difference in a long direction of the mouth ring, to introduce a plasma raw material gas into the mouth ring commensurate with the pressure difference, and

chemically reacting the plasma raw material gas, to make a thin film made of diamond or diamond-like carbon at portions of the circular introducing portion, the rectangular injecting portion and the wringing portion to which the green product material is contacted.

Moreover, this invention relates to an apparatus for fabricating a mouth ring to form a honeycomb-shaped green product which includes a circular introducing portion to introduce a green product material, a rectangular injecting portion to inject the green product material, and a wringing portion, which is located between the circular introducing portion and the rectangular injecting portion, to wring out the green product material of the circular introducing portion to the rectangular injecting portion, comprising:

a given plasma CVD apparatus, and

a pressure difference-creating means to create a given pressure difference along a long direction of the mouth ring,

wherein a given plasma raw material gas is introduced into the mouth ring commensurate with the pressure difference.

The inventors had intensely studied to develop a mouth ring for forming a honeycomb-shaped green product which has a large wear-resistance. As a result, they made an attempt to form, at a wringing portion of a mouth ring, a thin film made of diamond or diamond-like carbon which has a larger hardness than iron boride or the like as mentioned above. Such a diamond thin film or the like is made by mean of a plasma CVD method and so on.

According to the plasma CVD method, a given raw material gas is excited into plasma state by means of microwave or high frequency wave, and the thus obtained plasma raw material gas is introduced and chemically reacted on a given base material, to fabricate a given thin film. In the case that such a diamond thin film is made at the wringing portion of the mouth ring by means of the plasma CVD method, the plasma raw material gas must be introduced into the wringing portion.

Since the size of the circular introducing portion of the mouth ring is in the order of 1 mm, however, a sufficient plasma raw material gas can not be introduced deep in the mouth ring by the conventional plasma CVD method. As a result, the diamond thin film can not be formed at the wringing portion of the mouth ring which is located deep in the mouth ring, and thus, a large wear-resistance can not be imparted to the mouth ring.

In this point of view, the inventors had intensely studied to develop the introducing method of a plasma raw material gas deep in a mouth ring, so as to make a diamond thin film in a good condition and a sufficient thickness at the wring portion or the like of the mouth ring. As a result, according to the fabricating method of mouth ring and the fabricating apparatus of mouth ring of the present invention, a pressure difference-creating means is provided in a conventional plasma CVD apparatus, and a mouth ring for forming a honeycomb-shaped green product is placed into the plasma CVD apparatus, and then, a given pressure difference is created in the mouth ring in the long direction by means of the pressure difference creating means.

In this case, a large amount of plasma raw material gas which is generated in the plasma CVD apparatus is introduced into the mouth ring due to the pressure difference. As a result, a diamond or diamond-like carbon film can be easily formed in a large thickness at the wringing portion and so on of the mouth ring predetermined.

In a preferred embodiment of the fabricating method or the fabricating apparatus of the present invention, a magnetic field-generating means is provided in the plasma CVD apparatus including the pressure difference-creating means to generate a given magnetic field in the long direction of the mouth ring, the plasma raw material gas is introduced into the mouth ring with trapping the plasma raw material gas by means of the magnetic field. In this case, a large amount of plasma raw material gas can be introduced into the mouth ring efficiently.

In another preferred embodiment of the fabricating method or the fabricating apparatus of the present invention, an electric field-generating means is provided in the plasma CVD apparatus including the pressure difference-creating means, and the plasma raw material gas is introduced into the mouth ring along the electric field. In this case, too, a large amount of plasma raw material gas can be introduced into the mouth ring efficiently. Herein, the electric field-generating means may be combined with the magnetic field-generating means.

The plasma raw material gas may be made through the excitation of a given raw material gas by means of the electric field-generating means as mentioned above. In this case, since additional exciting means is not required to generate the plasma raw material gas, the entire structure of the fabricating apparatus can be simplified and the fabricating process of diamond thin film or the like can be simplified.

In the present invention, it is desired that the diamond or the diamond-like carbon thin film is made on an underfilm including Ti or Si. Since such an underfilm has a large adhesive force, the adhesion of the thin film for the mouth ring can be developed. Therefore, a large wear-resistance can be imparted to the mouth ring so as not to be worn even after a long time use.

### BRIEF DESCRIPTION OF THE DRAWINGS

For a better understanding of the invention, reference is made to the accompanying drawings:

FIG. 1 is a perspective view showing a portion of a mouth ring for forming a honeycomb-shaped green product,

FIG. 2 is a back side view of the mouth ring shown in FIG. 1,

FIG. 3 is a structural view showing a fabricating apparatus of mouth ring for forming a honeycomb-shaped green product according to the present invention,

FIG. 4 is a schematic view showing a mouth ring employed in an embodiment of the present invention,

FIG. 5 is a side elevational view of the mouth ring shown in FIG. 4, and

FIG. 6 is a graph showing a Raman spectrum of a diamond-like carbon thin film made at the wringing portion of the mouth ring shown in FIGS. 4 and 5, according to the fabricating method and the fabricating apparatus of the present invention.

### DESCRIPTION OF THE PREFERRED EMBODIMENTS

The invention will be described in detail below, with reference to the above drawings.

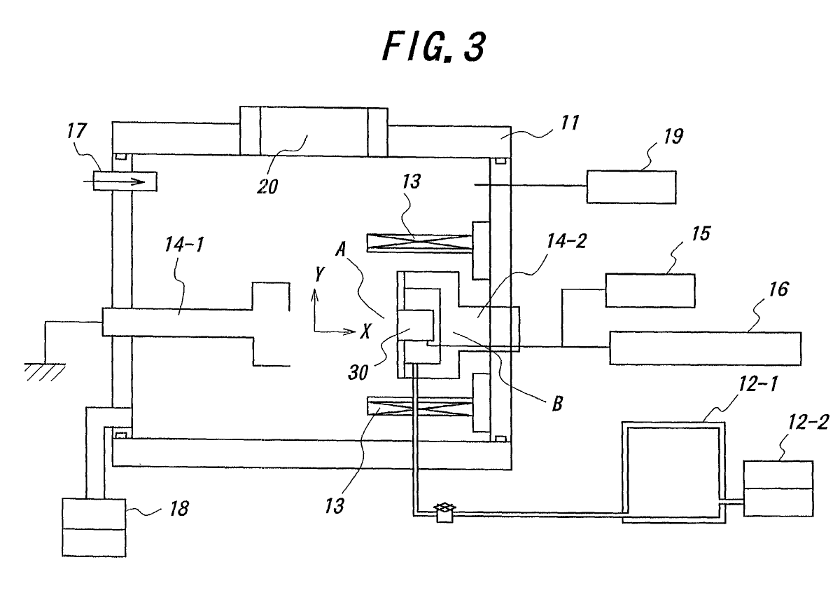

FIG. 3 is a schematic view showing a fabricating apparatus of mouth ring for forming a honeycomb-shaped green product according to the present invention. The fabricating apparatus includes a film-forming chamber 11, a pressure-regulating chamber 12-1 and a pump 12-2 as a pressure difference-creating means which are connected to the chamber 11, a coil 13 as a magnetic field-generating means, a positive electrode 14-1 and negative electrode 14-2 as an electric field-generating means. The positive electrode 14-1 is grounded, and the negative electrode 14-2 is connected to a DC power supply 15 and a high pressure-pulsed voltage power supply 16.

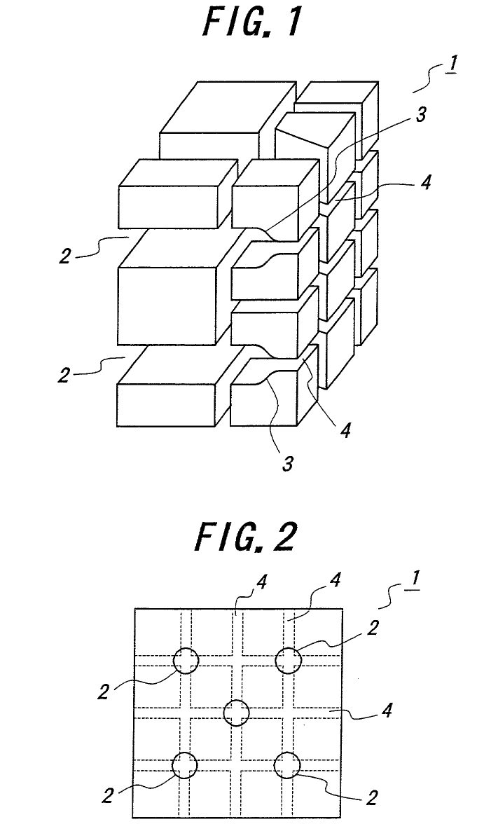

At the chamber 11 are provided a gas inlet 17 to introduce a given raw material gas and a pump 18 as an evacuating means to maintain the chamber 11 to a predetermined degree of vacuum. Also, at the chamber 11 are provided a pressure gauge 19 and a window 20 to monitor the degree of vacuum in the chamber 11 and the condition of a plasma raw material gas made through the excitation of the raw material gas introduced. A mouth ring 30 for forming a honeycomb-shaped green product has such a configuration as shown in FIGS. 1 and 2, and is fixed and set above the negative electrode 14-2.

A diamond or a diamond-like carbon thin film is made in the mouth ring 30, that is, at the circular introducing portion, the rectangular injecting portion and the wringing portion of the mouth ring 30 as follows.

First of all, the interior of the chamber 11 is evacuated up to a predetermined degree of vacuum with the pump 18, and a given raw material gas such as CH₄ gas is introduced into the chamber 11 from the gas inlet 17. Then, the introduction of the raw material gas into the chamber 11 and the evacuation for the interior of chamber 11 are balanced, to maintain the interior of the chamber 11 in a predetermined degree of vacuum. Herein, the degree of vacuum is monitored by means of the pressure gauge 19.

Then, a given pulsed voltage is applied to the mouth ring 30 from the high pressure-pulsed voltage power supply 16 with applying a given DC biasing voltage to the mouth ring 30 from the DC power supply 15, to excite the raw material gas in plasma state.

Then, the space around the negative electrode 14-2 where the mouth ring 30 is located is evacuated via the pressure regulating chamber 12-1 by means of the pump 12-2, to create a given pressure difference in the long direction of the mouth ring 30 along the X-direction. The pressure difference is preferably determined so that the pressure in the back space B of the mouth ring 30 along the X-direction is set to be tenth or below, particularly centesimal or below of the pressure in the front space A of the mouth ring 30 along the X-direction. In this case, the plasma raw material gas can be introduced into the mouth ring 30 efficiently.

Concretely, since the pressure of the chamber 11 is set to about 10⁻² Torr and the pressure in the front space A of the mouth ring 30 is set to about 10⁻² Torr, the pressure in the back space B of the mouth ring 30 is preferably set to a pressure within a range of 10⁻³-10⁻⁴ Torr by means of the pressure regulating chamber 12-1 and the pump 12-2.

Then, a given magnetic field is generated in the long direction of the mouth ring 30 along the X-direction by flowing a current in the coil 13. The magnetic field is preferably converged in the Y-direction perpendicular to the X-direction so that the dimension of the magnetic field is set to be in the order of the outside diameter. In this case, a large amount of plasma raw material gas can be introduced into the mouth ring 30, and thus, a thin film made of diamond or diamond-like carbon can be made in a large thickness in the mouth ring 30.

Supposed that the minimum diameter of portions of the circular introducing portion, the rectangular injecting portion and the wringing portion of the mouth ring 30, to which a green product material is contacted under a pressure condition, is defined as “r”, the strength of the magnetic field is preferably set to 2.0×10⁻⁷/r (T) or over. Concretely, supposed that the minimum diameter “r” is set to 1.0 mm, the magnetic field is preferably set within 1.0×10⁻⁴×3.0×10⁻⁴T, particularly within 2.0×10⁻⁴−3.0×10⁻⁴T. In this case, the plasma raw material gas can be trapped by the magnetic field more efficiently, and thus, a large amount of plasma raw material gas can be introduced into the mouth ring 30. As a result, a thin film made of diamond or diamond-like carbon can be made in the mouth ring easily and efficiently.

Also, a given electric field is generated toward the positive electrode 14-1 from the negative electrode 14-2 by the DC biasing voltage and the pulsed voltage which are utilized to generate the plasma raw material gas. Therefore, the plasma raw material gas is introduced into the mouth ring 30 efficiently by means of the electric field. As a result, a large amount of plasma raw material gas can be introduced into the mouth ring 30, and thus, a thin film made of diamond or diamond-like carbon can be made in the mouth ring easily and efficiently.

The strength of the electric field is preferably set within 20-200 kV/m, particularly within 20-100 kV/m. In the fabricating apparatus shown in FIG. 3, the electric field strength of the above range can be realized by controlling the DC voltage and the pulsed voltage within given ranges to generate the plasma gas, respectively.

In the fabricating apparatus shown in FIG. 3, as mentioned above, since the magnetic field and the electric field are generated along the X-direction, in addition to the pressure difference, the plasma raw material gas can be introduced into the mouth ring 30 more efficiently, so that a thin film made of diamond or diamond-like carbon can be made in a large thickness at the wringing portion and so on of the mouth ring 30. Therefore, a large wear-resistance can be imparted to the mouth ring 30.

It is desired that an underfilm including Ti or Si is made in the mouth ring before the above thin film is made. Since such an underfilm has a large adhesive force, the adhesion of the thin film can be developed for the interior of the mouth ring.

As such an underfilm including Ti, a TiCN film, a TiC film, a TiN film and a Ti film are exemplified. Particularly, a TiCN film is preferably used. As such an underfilm including Si, a Si film, a SiC film, a Si₃N₄ film are exemplified. Particularly, a Si film is preferably used.

Such an underfilm may be made by utilizing the apparatus shown in FIG. 3 before the thin film of wear-resistance made of diamond or the like is made. In this case, the underfilm is made in the same manner as the thin film is made.

In making a TiCN underfilm, TiCl₄ is employed as a Ti raw material gas and CH₃CN is employed as a carbon/nitrogen raw material gas.

### EXAMPLE

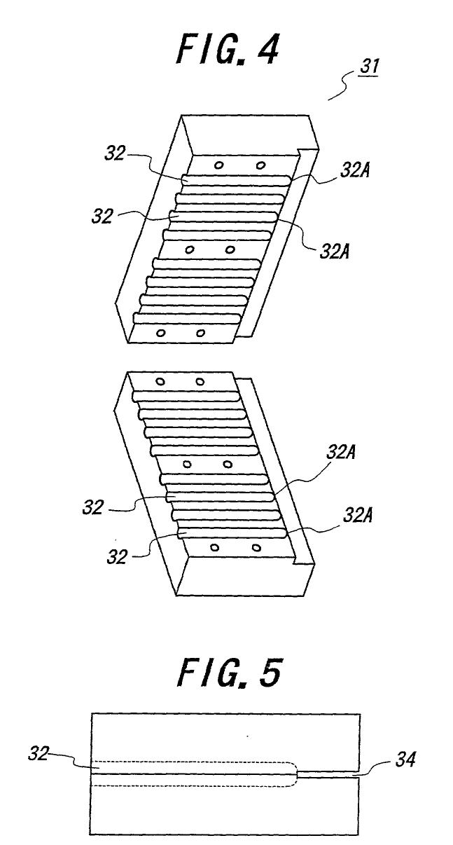

This invention will be described concretely hereinafter. In this Example, a thin film made of diamond-like carbon was made in a mouth ring for forming a honeycomb-shaped green product by utilizing the fabricating apparatus shown in FIG. 3. Also such a mouth ring 31 is employed as shown in FIG. 4 where two members, each having plural circular introducing portions, are combined so that the circular introducing portions are matched respectively. When a diamond-like carbon thin film is observed, the mouth ring 31 is opened vertically and divided into the original two members. Therefore, the observation for the diamond-like carbon thin film can be carried out easily.

FIG. 5 is a side elevational view showing the mouth ring where the two members are combined. As is apparent from FIG. 5, the rectangular injecting portion of the mouth ring 31 is constructed of the gap between the two members combined. Moreover, the wringing portion of the mouth ring 31 is constructed of the bottom portions 32A of the circular introducing portions 32 which are combined.

First of all, the mouth ring 31 was fixed and set above the negative electrode 14-2, and the interior of the film-forming chamber 11 was evacuated up to 10⁻⁵ Torr by mean of the pump 18. Then, a CH₄ gas was introduced from the gas inlet 17 at a flow rate of 20 cm³/min, and then, the interior pressure of the chamber 11 was maintained at 3.75×10⁻² Torr through the evacuation by means of the pump 18. Subsequently, a voltage of 1.5 kV was applied between the positive electrode 14-1 and the negative electrode 14-2 from the DC power supply 15 and the high pressure-pulsed voltage power supply 16, to generate a CH₄ gas plasma. In this case, an electric field having a strength of 30 kV/m was generated between the positive electrode 14-1 and the negative electrode 14-2.

Then, the pressure in the back side space of the mouth ring 31 along the X-direction was set to 4.5×10⁻⁴ Torr by means of the pressure regulating chamber 12-1 and the pump 12-2. Moreover, a magnetic field having a strength of 0.01T was generated along the X-direction by flowing a current in the coil 13.

The above condition was maintained for 15 minutes so that the CH₄ gas plasma was introduced into the mouth ring 31 and then, a diamond-like carbon thin film was made at the circular introducing portions 32, the wringing portions 32A and the rectangular injecting portions 34 of the mouth ring 31 through the chemical reaction of the CH₄ gas plasma Thereafter, the mouth ring 31 was opened vertically, and a diamond-like carbon thin film made at the wringing portion was investigated.

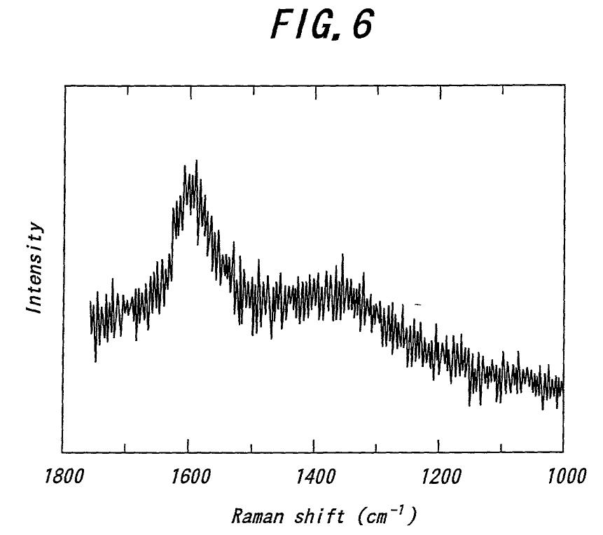

FIG. 6 is a graph showing a Raman spectrum of the diamond-like carbon thin film. As is apparent from FIG. 6, absorption peaks due to diamond-like carbon are observed around 1360 cm⁻¹ and 1580 cm⁻¹, so that it is turned out that the diamond-like carbon thin film is excellent in quality.

According to the fabricating method and the fabricating apparatus of the present invention, therefore, such a diamond-like carbon thin film of good quality can be made at the wringing portion of the mouth ring 31 which is constructed of two member combined, and thus, a large wear-resistance can be imparted to the mouth ring 31.

This invention has been described in detail with reference to the above preferred concrete embodiments, but it is obvious for the ordinary person skilled in the art that various modifications can be made in its configuration and detail without departing from the scope of this invention.

According to the fabricating method of mouth ring for forming a honeycomb-shaped green product and the fabricating apparatus of mouth ring for forming a honeycomb-shaped green product of the present invention, as mentioned above, a pressure difference is created in the long direction of a mouth ring, and thus, a given plasma raw material gas is introduced by utilizing the pressure difference. Therefore, a large amount of plasma raw material gas can be introduced into the circular introducing portion of minute size of the mouth ring and then, chemically reacted. Therefore, a thin film made of diamond or diamond-like carbon having a large wear-resistance can be made at the wringing portion and so on of the mouth ring.

What is claimed is:

1. A mouth ring for forming a honeycomb-shaped green product, comprising:
a circular introducing portion to introduce a given green product material,
a rectangular injecting portion to inject said green product material,
a wringing portion to wring out said green product material of said circular introducing portion to said rectangular injecting portion, said wringing portion being located between said circular introducing portion and said rectangular injecting portion, and
a thin film made of diamond or diamond-like carbon which is made at portions of said circular introducing portion, said rectangular injecting portion and said wringing portion to which said green product material is contacted.

2. A mouth ring as defined in claim 1, wherein said thin film is made at said wringing portion.

3. A mouth ring as defined in claim 1, further comprising an underfilm, wherein said thin film is made via said underfilm.

4. A mouth ring as defined in claim 3, wherein said underfilm is made of TiCN.

5. A method for fabricating a mouth ring to form a honeycomb-shaped green product which includes a circular introducing portion to introduce a green product material, a rectangular injecting portion to inject said green product material, and a wringing portion, which is located between said circular introducing portion and said rectangular injecting portion, to wring out said green product material of said circular introducing portion to said rectangular injecting portion, comprising the steps of:
preparing a plasma CVD apparatus,
setting said mouth ring in said plasma CVD apparatus,
creating a pressure difference in a long direction of said mouth ring, to introduce a plasma raw material gas into said mouth ring commensurate with said pressure difference, and
chemically reacting said plasma raw material gas, to make a thin film made of diamond or diamond-like carbon at portions of said circular introducing portion, said rectangular injecting portion and said wringing portion to which said green product material is contacted.

6. A fabricating method as defined in claim 5, wherein said pressure difference is determined so that the pressure in the back side space of said mouth ring is set to be tenth or below of the pressure in the front space of said mouth ring.

7. A fabricating method as defined in claim 5, further comprising the step of generating a given magnetic field along said long direction of said mouth ring, wherein said plasma raw material gas is introduced into said mouth ring with trapped by said magnetic field.

8. A fabricating method as defined in claim 7, wherein the strength of said magnetic field is set to 2.0×10-7/r (T) or over, on condition that the minimum diameter of portions of said circular introducing portion, said rectangular injecting portion and said wringing portion of said mouth ring to which said green product material is contacted is set to “r”.

9. A fabricating method as defined in claim 5, further comprising the step of generating a given electric field along said long direction of said mouth ring, wherein said plasma raw material gas is introduced into said mouth ring commensurate with said electric field.

10. A fabricating method as defined in claim 9, wherein the strength of said electric field is set within 20-200 kV/m.

11. A fabricating method as defined in claim 5, further comprising the step of making an underfilm including Ti, wherein said thin film is made via said underfilm.

12. A fabricating method as defined in claim 11, wherein said underfilm is made of TiCN.

13. An apparatus for fabricating a mouth ring to form a honeycomb-shaped green product which includes a circular introducing portion to introduce a green product material, a rectangular injecting portion to inject said green product material, and a wringing portion, which is located between said circular introducing portion and said rectangular injecting portion, to wring out said green product material of said circular introducing portion to said rectangular injecting portion, comprising:
a given plasma CVD apparatus, and
a pressure difference-creating means to create a given pressure difference along a long direction of said mouth ring,
wherein a given plasma raw material gas is introduced into said mouth ring commensurate with said pressure difference.

14. A fabricating apparatus as defined in claim 13, wherein by means of said pressure difference-creating means, the pressure in the back side space of said mouth ring is set to be tenth or below of the pressure in the front space of said mouth ring.

15. A fabricating apparatus as defined in claim 13, further comprising a magnetic field-generating means to generate a given magnetic field along said long direction of said mouth ring, wherein said plasma raw material gas is introduced into said mouth ring with trapped by said magnetic field.

16. A fabricating apparatus as defined in claim 13, further comprising an electric field-generating means to generate a given electric field along said long direction of said mouth ring, wherein said plasma raw material gas is introduced into said mouth ring commensurate with said electric field.
